(19) United States
(12) Patent Application Publication
(10) Pub. No.: US 2006/0089001 A1
(43) Pub. Date: Apr. 27, 2006

(54) Localized use of high-K dielectric for high performance capacitor structures

(76) Inventors: Sean Christopher Erickson, Fort Collins, CO (US); Jay Tatsuo Fukumoto, Fort Collins, CO (US)

Correspondence Address: LSI Logic Corporation;Legal Department - IP, 1621 Barber Lane, MS D-106, Milpitas, CA, 95035, US

(21) Appl. No.: 10/974,115

(22) Filed: Oct. 27, 2004

(51) Int. Cl. H01L 21/311; H01L 21/302

(52) U.S. Cl. 438/694; 438/718; 438/720

(57) ABSTRACT

Techniques are provided for localized use of high-K dielectric material within a capacitor structure. Low-K dielectric is deposited or spun on as usual. Then, a larger area is etched back and then filled with high-K dielectric material. The high-K dielectric material is then patterned and copper routing lines are trenched in and then filled with metal. A dual damascene process may be used to connect a second metal layer using a series of vias for each metal line. In an aluminum process, an insulator layer is formed over the substrate and an aluminum layer is formed over the insulator layer. The aluminum layer is etched back to for metal lines over the insulator layer. The remaining area is filled with low-K dielectric. Then, the area between the metal lines is etched back and filled with high-K dielectric to increase the capacitance value of the structure.

### BACKGROUND OF THE INVENTION

1. Technical Field

The present invention is directed generally toward capacitor structures. More particularly, the present invention relates to a method and apparatus for localized use of high-K dielectric for high performance capacitor structures.

2. Description of the Related Art

Low-K dielectrics are materials with a low dielectric constant (K) that are used as insulators in semiconductor devices to reduce parasitic effects, such as resistance, capacitance, and crosstalk. In fact, use of low-K dielectrics has become the standard for parasitic reduction between metal routing lines. With the accepted use of low-K dielectrics, capacitors and other structures are typically formed in the low-K dielectric layer. For example, one may simply etch trenches in the dielectric layer and fill the trenches with metal lines, which may also form plates in a capacitor structure. In this example, the metal lines are separated by the low-K dielectric, thus making up a capacitor structure.

However, the widespread use of low-K dielectrics affects metal dielectric capacitor structures that work upon parasitic effects, such as the fence, grid, and other multi-metal layer capacitor structures. With the use of low-K dielectrics, the capacitor value is intentionally lessened, forcing the use of bigger and deeper (i.e. more metal layers) structures to form capacitors with larger capacitance values. These structures not only take up more chip area, but also have increased parasitics due to a larger cross sectional area. Therefore, while low-K dielectrics are advantageous for reducing parasitic effects in semiconductor devices, they are not ideal for other structures.

### SUMMARY OF THE INVENTION

The present invention recognizes the disadvantages of the prior art and provides techniques for localized use of high-K dielectric material within a capacitor structure. In one exemplary embodiment, low-K dielectric is deposited or spun on as usual. Then, a larger area is etched back and then filled with high-K dielectric material. The high-K dielectric material is then patterned and copper routing lines are trenched in and then filled with metal.

In another exemplary embodiment, a dual damascene process is used to connect a second metal layer using a series of vias for each metal line. A doubly thick layer of low-K dielectric is formed over the area of the capacitor structure. As in the single damascene process the area for the capacitor is etched away using known processes. This area is filled in with high-K dielectric to increase the capacitance value of the structure. The high-K dielectric is patterned and etched, the vias and metal lines are then formed over and electrically connecting to the first metal layer. More metal layers and their connecting vias may then be formed using the same process.

In yet another exemplary embodiment, an insulator layer is formed over the substrate and an aluminum layer is formed over the insulator layer. The aluminum layer is etched back to form metal lines over the insulator layer. The remaining area is filled with low-K dielectric. Then, the area between the metal lines is etched back and filled with high-K dielectric to increase the capacitance value of the structure.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIGS. 1A-1E depict the fabrication of a metal-insulator-metal capacitor structure using a single damascene process in accordance with an exemplary embodiment of the present invention;

FIG. 2 is a flowchart illustrating a process for fabricating a metal-insulator-metal capacitor structure using a single damascene process in accordance with an exemplary embodiment of the present invention;

FIGS. 3A-3G depict the fabrication of a metal-insulator-metal capacitor structure using a dual damascene process in accordance with an exemplary embodiment of the present invention;

FIG. 4 illustrates a multiple layer capacitor structure using a single damascene process for the bottom layer and a dual damascene process for the upper layers in accordance with an exemplary embodiment of the present invention;

FIGS. 5A-5F depict the fabrication of a metal-insulator-metal capacitor structure using an aluminum process in accordance with an exemplary embodiment of the present invention; and

FIG. 6 is a flowchart illustrating a process for fabricating a metal-insulator-metal capacitor structure using an aluminum process in accordance with an exemplary embodiment of the present invention.

### DETAILED DESCRIPTION

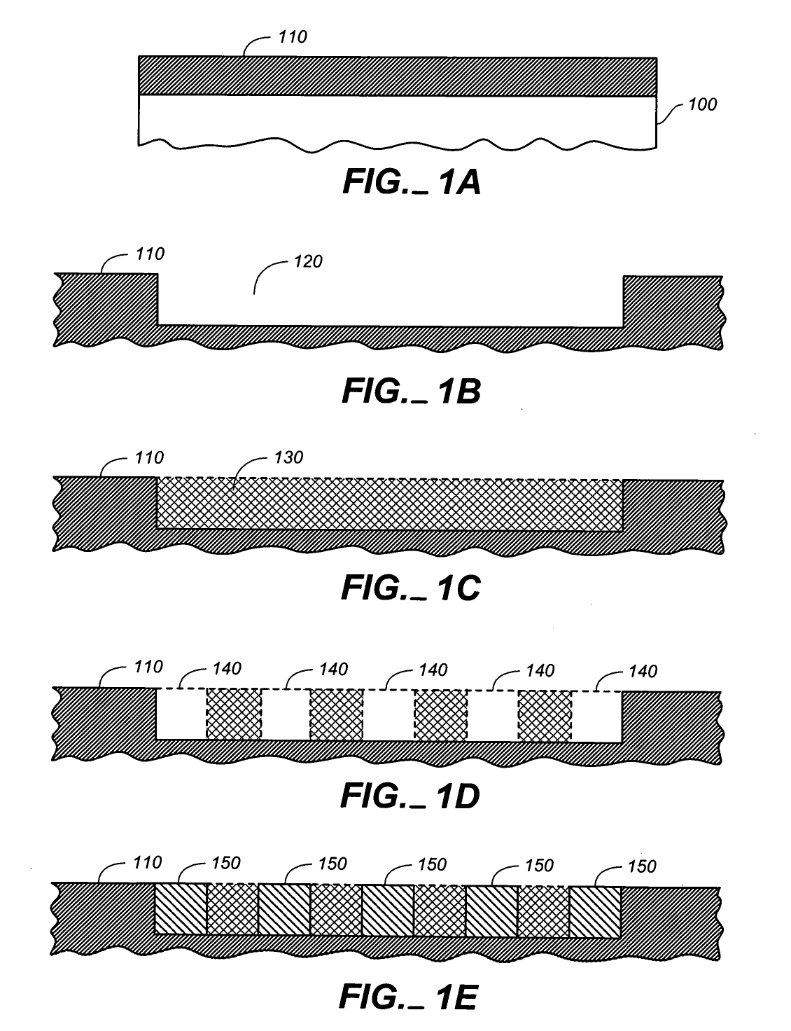

With reference now to the figures, FIGS. 1A-1E depict the fabrication of a metal-insulator-metal capacitor structure using a single damascene process in accordance with an exemplary embodiment of the present invention. With reference to FIG. 1A, a substrate 100 is shown with a low-K dielectric layer 110 form thereon. The low-K dielectric layer may be deposited or spun on the substrate, for example, using known techniques. A low-K dielectric layer is commonly used to reduce parasitic effects, such as resistance, capacitance, and crosstalk, for example. The low-K dielectric material may be Black Diamond™ (silicon carbide (SiC)), for example. A typical range of dielectric constant for a low-K dielectric material may be anything lower than 3.9, but may be in the range of 2.7 to 2.9 in a preferred embodiment.

Turning to FIG. 1B, a localized area 120 is etched into the low-K dielectric layer 110. The localized area 120 may be etched using known photolithography techniques, for example. In FIG. 1C, the localized area is then filled with high-K dielectric material 130. The high-K material may be hafnium silicate (HfSiO₄) with a dielectric constant approximately equal to 10, for example. However, the high-K material is preferably any material that has a dielectric constant greater than 3.9. A chemical/mechanical polishing (CMP) technique may then be used to smooth the finish.

Next, with reference to FIG. 1D, trenches 140 are etched into the high-K dielectric material for metal routing lines. The trenches may be etched using known photolithography techniques, for example. Thereafter, the trenches are filled with metal 150 to form metal plates in the capacitor structure, as shown in FIG. 1E. The metal may be copper (Cu), for example. The resulting structure shown in FIG. 1E is a metal-insulator-metal capacitor structure with a higher capacitance value due to the high-K dielectric.

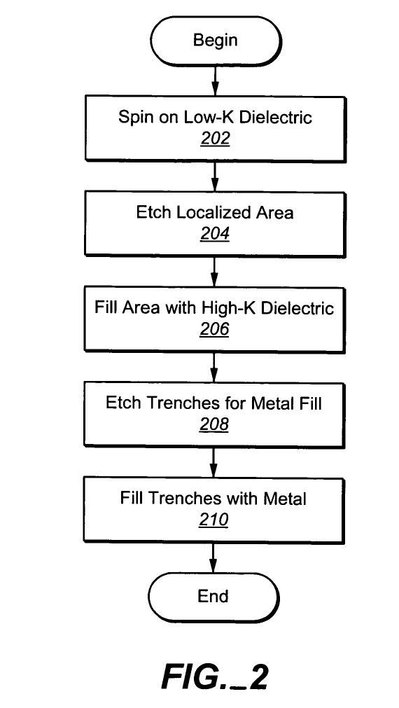

FIG. 2 is a flowchart illustrating a process for fabricating a metal-insulator-metal capacitor structure using a single damascene process in accordance with an exemplary embodiment of the present invention. The process begins and spins on a low-K dielectric (block 202). Then, the process etches a localized area (block 204) and fills the area with a high-K dielectric (block 206). Next, the process etches trenches for metal fill (block 208). Thereafter, the trenches are filled with metal (block 210) and the process ends.

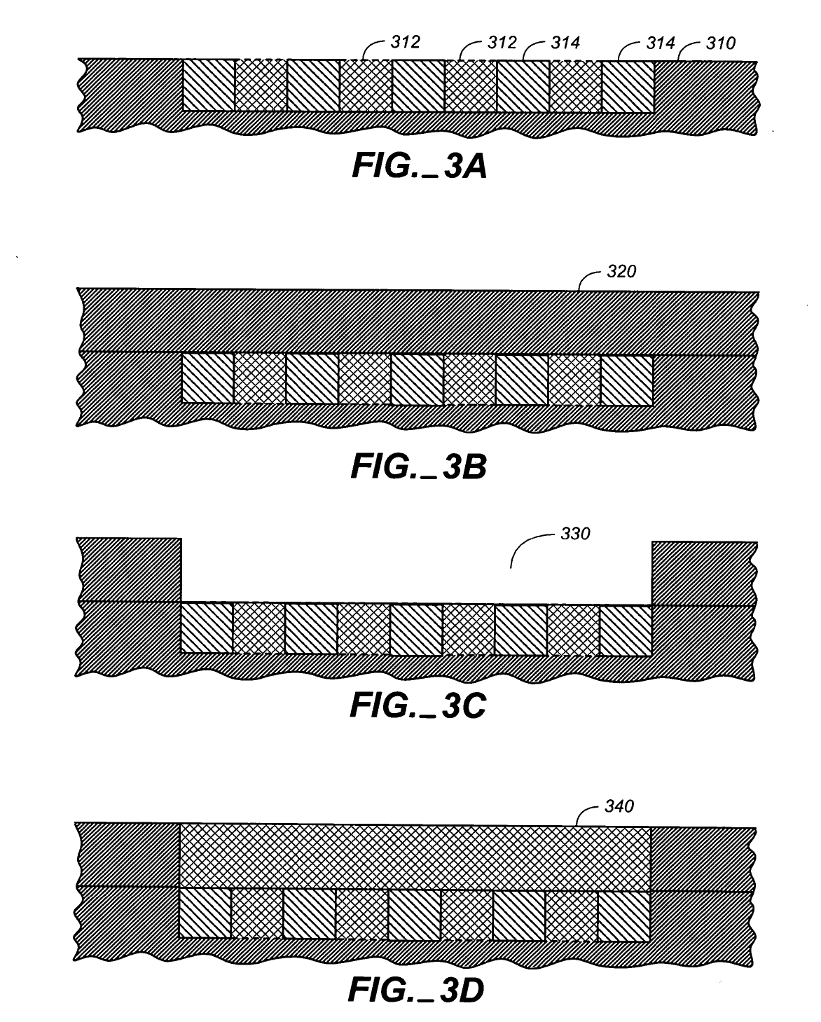

FIGS. 3A-3G depict the fabrication of a metal-insulator-metal capacitor structure using a dual damascene process in accordance with an exemplary embodiment of the present invention. In a dual damascene process, connecting vias and a top layer of metal are created in the same process step. More particularly, with reference to FIG. 3A, a first metal layer is formed in low-K dielectric 310 with metal lines 314 being separated by high-K dielectric material 312 using the process describes above with reference to FIGS. 1A-1E and FIG. 2. Then, as shown in FIG. 3B, low-K dielectric 320 is formed over the first metal layer. The low-K dielectric 320 may be formed by spinning a dielectric material over the first metal layer.

Next, turning to FIG. 3C, localized area 330 is etched away. The localized area 330 for a second metal layer is filled with high-K dielectric 340 as shown in FIG. 3D. With reference now to FIG. 3E, trenches 352 for metal lines in a second metal layer are etched into the high-K dielectric. Similarly, as illustrated in FIG. 3F, trenches 354 for vias connecting the second metal layer to the first metal layer are then etched into the high-K dielectric. The via holes and metal line trenches are filled in with metal 360 as shown in FIG. 3G. The metal for vias and metal lines 360 may be copper (Cu), for example. The vias are created at the same time as metal lines. For typical dimensions, the vias may be, for example, 0.19 μm wide and 0.37 μm tall. The height of the vias may be between 0.3 μm minimum and 0.44 μm maximum. For typical dimensions, the metal lines may be, for example, 0.2 μm wide and 0.35 μm tall. The height for the metal lines may be between 0.25 μm minimum and 0.45 μm maximum. The first layer of metal lines may have the same dimensions as the second layer of metal lines.

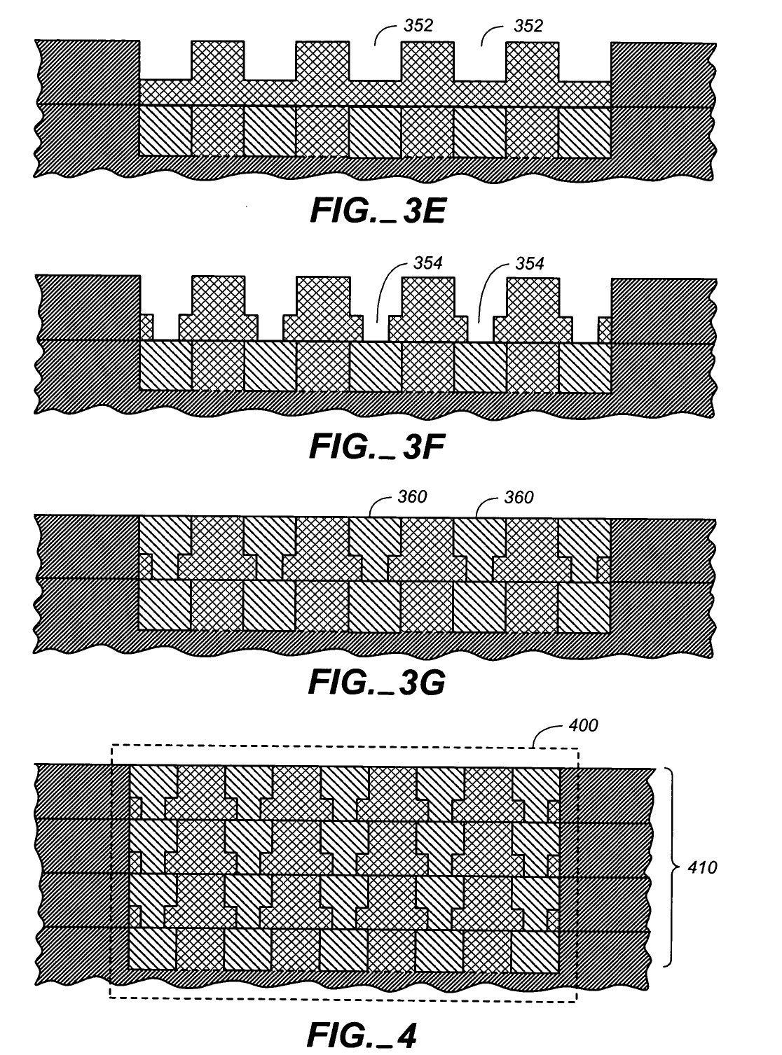

Typical dimensions for the high-K fill between metal lines may be 0.16 μm; however, the width of the high-K between metal lines may range from 0.14 μm minimum to 0.18 μm maximum. The closer (thinner) the high-K spacing between metal lines, the higher the capacitance. The process shown in FIGS. 3A-3G may be repeated to add subsequent metal lines. FIG. 4 illustrates a multiple layer capacitor structure using a single damascene process for the bottom layer and a dual damascene process for the upper layers in accordance with an exemplary embodiment of the present invention. In the depicted example, capacitor structure 400 includes four metal layers 410; however, more or fewer metal layers may be used depending upon the particular structure being fabricated.

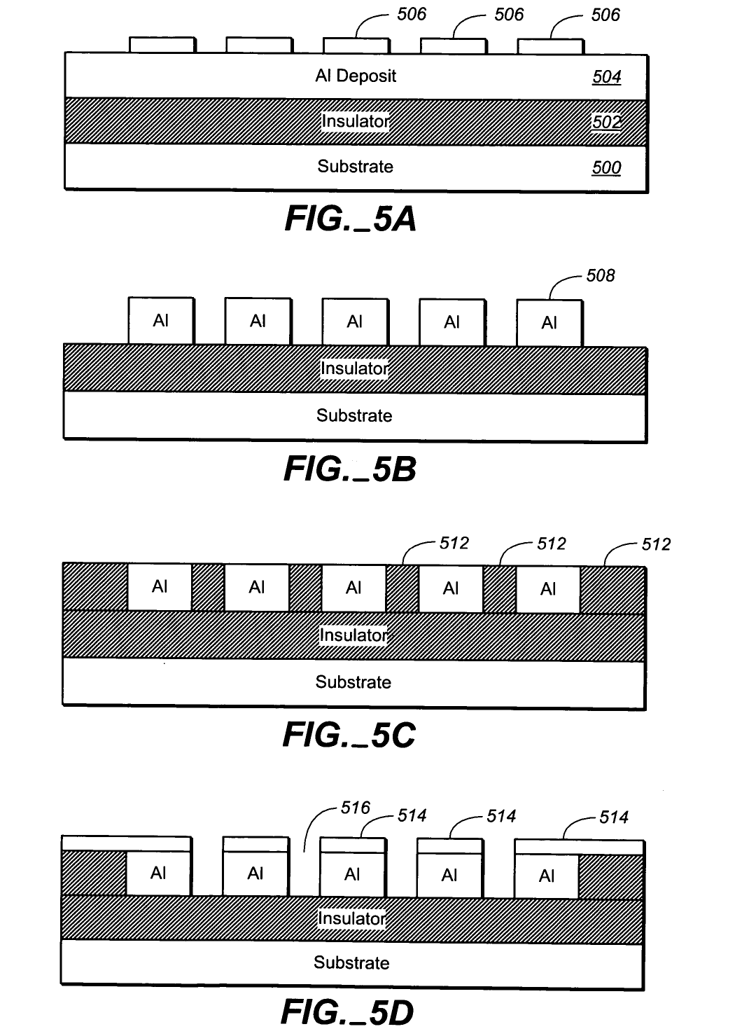

FIGS. 5A-5F depict the fabrication of a metal-insulator-metal capacitor structure using an aluminum process in accordance with an exemplary embodiment of the present invention. In an aluminum process, each layer is formed by depositing aluminum (Al) and then patterning and etching away the unwanted line or vias. More particularly, with reference to FIG. 5A, insulator layer 502 is formed on substrate 500. Insulator 502 may be a low-K dielectric material, such as SiC. Aluminum layer 504 is then deposited over insulator layer 502. Photoresist 506 is then patterned on aluminum layer 504.

Using photoresist 506 to shield the aluminum from etching, unwanted aluminum is etched away to form aluminum lines 508, as shown in FIG. 5B. The photoresist is polished off using CMP. Then, as shown in FIG. 5C, insulator 512 is deposited, spun, or grown to fill the voids. Turning to FIG. 5D, photoresist 514 is patterned for selective etching. Spaces 516 between the aluminum lines are etched. Thereafter, as shown in FIG. 5E, the spaces are filled with high-K dielectric 518. With reference now to FIG. 5F, the photoresist is polished away to form a metal-insulator-metal capacitor structure. Additional layers and their connecting vias may be added as desired.

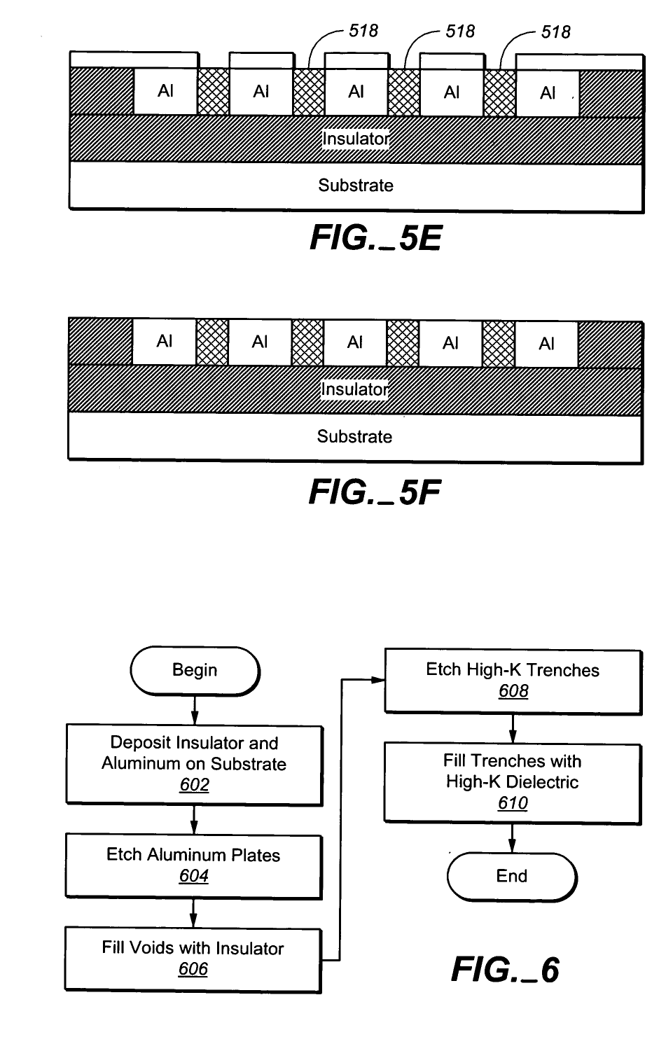

FIG. 6 is a flowchart illustrating a process for fabricating a metal-insulator-metal capacitor structure using an aluminum process in accordance with an exemplary embodiment of the present invention. The process begins and deposits an insulator layer and aluminum layer on the substrate (block 602). Then, the process etches the aluminum plates (lines) (block 604) and fills the voids with insulator material (block 606). Next, the process etches trenches between the metal lines (block 608) and fills the trenches with high-K dielectric (block 610). Thereafter, the process ends.

Thus, the present invention solves the disadvantages of the prior art by providing a technique for localized use of high-K dielectric material within a capacitor structure. The resulting capacitor structures have higher capacitance while reducing die area. Since the capacitor structures of the present invention may be formed in a smaller die area, the resulting parasitic effects, such as crosstalk, for example, are reduced. Furthermore, these structures may be formed using existing fabrication techniques and without significant cost.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention and the practical application and to enable others of ordinary skill in the art to understand the invention for various embodiments with various modifications as are suited to the particular use contemplated.

What is claimed is:

1. A method of forming a capacitor structure, the method comprising:
forming a first dielectric layer of a first dielectric material on a substrate, wherein the first dielectric material has a first dielectric constant;
etching a localized area into the first dielectric layer;
filling the localized area with a second dielectric material, wherein the second dielectric material has a second dielectric constant and wherein the second dielectric constant is high relative to the first dielectric constant;
etching trenches in the second dielectric material for metal lines; and
filling the trenches with metal to form a metal layer.

2. The method of claim 1, wherein the first dielectric constant is less than 3.9.

3. The method of claim 1, wherein the first dielectric material is silicon carbide.

4. The method of claim 1, wherein the second dielectric constant is greater than 3.9.

5. The method of claim 1, wherein the second dielectric material is hafnium silicate.

6. The method of claim 1, wherein the metal is copper.

7. The method of claim 1, wherein the metal layer is a first metal layer, the method further comprising:
forming a second dielectric layer over the first metal layer;
etching a second localized area into the second dielectric layer;
filling the second localized area with the second dielectric material;
etching trenches for vias and metal lines in the second dielectric material in the second localized area;
filling the trenches with metal to form a second metal layer.

8. A method of forming a capacitor structure, the method comprising:
forming a dielectric layer of a first dielectric material on a substrate, wherein the first dielectric material has a first dielectric constant;
forming an aluminum layer over the dielectric layer;
etching the aluminum layer to form metal lines;
filling a remainder of area around the metal lines with the first dielectric material;
etching an area between the metal lines to form trenches; and
filling the trenches with a second dielectric material, wherein the second dielectric material has a second dielectric constant and wherein the second dielectric constant is high relative to the first dielectric constant.

9. The method of claim 8, wherein the first dielectric constant is less than 3.9.

10. The method of claim 8, wherein the first dielectric material is silicon carbide.

11. The method of claim 8, wherein the second dielectric constant is greater than 3.9.

12. The method of claim 8, wherein the second dielectric material is hafnium silicate.

13. An apparatus, comprising:
a dielectric layer of a first dielectric material on a substrate, wherein the first dielectric material has a first dielectric constant; and
a capacitor structure within the dielectric layer, wherein the capacitor structure includes metal lines separated by a second dielectric material, wherein the second dielectric material has a second dielectric constant and wherein the second dielectric constant is high relative to the first dielectric constant.

14. The apparatus of claim 13, wherein the first dielectric constant is less than 3.9.

15. The apparatus of claim 13, wherein the first dielectric material is silicon carbide.

16. The apparatus of claim 13, wherein the second dielectric constant is greater than 3.9.

17. The apparatus of claim 13, wherein the second dielectric material is hafnium silicate.

18. The apparatus of claim 13, wherein the metal is copper.

19. The apparatus of claim 13, wherein the metal is aluminum.
